(19) United States
(12) Patent Application Publication
(10) Pub. No.: US 2009/0233439 A1
(43) Pub. Date: Sep. 17, 2009

(54) Method of forming an ohmic layer and method of forming a metal wiring of a semiconductor device using the same

(76) Inventors: Myung-Beom Park, Hwaseong-si (KR); Ki-Hag Lee, Seoul (KR); Hyun-Su Kim, Suwon-si (KR); Eun-Ok Lee, Hwaseong-si (KR); Kyoo-Chul Cho, Yongin-si (KR); Jung-Sik Choi, Seongnam-si (KR); Byung-Hee Kim, Seoul (KR); Dae-Yong Kim, Yongin-si (KR)

Correspondence Address: LEE & MORSE, P.C., 3141 FAIRVIEW PARK DRIVE, SUITE 500, FALLS CHURCH, VA, 22042, US

(21) Appl. No.: 12/382,008

(22) Filed: Mar. 5, 2009

(30) Foreign Application Priority Data
Mar. 5, 2008 (KR) 2008-0020510

(51) Int. Cl. H01L 21/768

(52) U.S. Cl. 438/655; 257/E21.585

(57) ABSTRACT

A metal organic precursor represented by a formula of R₁-CpML is provided onto a substrate having a conductive pattern including silicon. Here, R₁ is an alkyl group substituent of Cp, R₁ including methyl, ethyl, propyl, pentamethyl, pentaethyl, diethyl, dimethyl or dipropyl, Cp is cyclopentadienyl, M includes nickel (Ni), cobalt (Co), titanium (Ti), platinum (Pt) zirconium (Zr) or ruthenium (Ru), and L is at least one ligand, the at least one ligand including a carbonyl. A deposition process is performed using the metal organic precursor to form a preliminary metal silicide layer and a metal layer on the substrate. The preliminary metal silicidation layer is formed on the conductive pattern. The preliminary metal silicide layer is transformed into a metal silicide layer.

### BACKGROUND

1. Field

Example embodiments relate to a method of forming an ohmic layer and a method of forming a metal wiring of a semiconductor device. More particularly, example embodiments relate to a method of forming an ohmic layer using a metal organic precursor and a method of forming a metal wiring of a semiconductor device using a metal organic precursor.

2. Description of the Related Art

As semiconductor devices become more highly integrated, sizes of gate electrodes and impurity regions serving as source/drain regions in a transistor have been reduced. Due to the reduction of the sizes of the gate electrodes, channel lengths of the transistor may be reduced, which may deteriorate electrical characteristics of the transistor. When a wiring contacting the source/drain regions includes polysilicon, the wiring may have high contact resistance or high sheet resistance. As a result, a semiconductor device including such a transistor may not perform high speed operation and power consumption thereof may be increased. Thus, metal wiring is typically used as the wiring contacting the source/drain regions of the transistor.

Generally, a metal wiring has an ohmic layer including a metal silicide, a capping layer, and a metal plug. The ohmic layer may be formed by reaction of a metal layer with silicon in a silicon substrate after forming the metal layer on the silicon substrate. For example, the metal layer may be formed using cobalt. The cobalt layer may be formed by a chemical vapor deposition (CVD) process in which a cobalt precursor such as dicobalt hexacarbonyl t-butylacetylene (CCTBA) is reacted with hydrogen (H₂). The cobalt layer formed by the above process may have low resistivity and good step coverage. However, the cobalt layer formed using the precursor may have bad morphology because the precursor is thermally decomposed at a low temperature, e.g., below about 250° C. used to form the cobalt layer. Additionally, when the ohmic layer is formed by a silicidation process, silicon atoms included in the silicon substrate may overly react with cobalt, causing the cobalt silicide layer to have an undesirably large thickness.

### SUMMARY

Example embodiments are therefore directed to a method of forming an ohmic layer using a metal organic precursor and a method of forming a metal wiring of a semiconductor device, which substantially overcome one or more of the disadvantages of the related art.

It is a feature of an embodiment to provide a method of forming an ohmic layer using a metal organic precursor including a cyclopentadienyl ligand and another ligand.

According to example embodiments, a method of forming an ohmic layer is provided. In the method, a metal organic precursor represented by a formula of R₁-CpML is provided onto a substrate having a conductive pattern including silicon thereon. Here, R₁ is an alkyl group substituent of Cp, R₁ including one of methyl, ethyl, propyl, pentamethyl, pentaethyl, diethyl, dimethyl or dipropyl, Cp is cyclopentadienyl, M includes nickel (Ni), cobalt (Co), titanium (Ti), platinum (Pt) zirconium (Zr) or ruthenium (Ru), and L is at least one ligand, the at least one ligand including a carbonyl. A deposition process is performed using the metal organic precursor to form a preliminary metal silicide layer and a metal layer on the substrate. The preliminary metal silicidation layer is formed on the conductive pattern. The preliminary metal silicide layer is transformed into a metal silicide layer.

In an example embodiment, L may include (CO)₂, (CO)₃(NO), (CO)₆:(HC≡C^{t}Bu), (CO)₆:(HC≡CPh), (CO)₆:(HC≡CH), (CO)₆:(HC≡CCH₃), (CO)₆:(CH₃C≡CCH₃), (CO)(NO), (CO)₂:(HC≡CtBu), (CO)₂:(HC≡CPh) (CO)₂:(HC≡CH), (CO)₂:(HC≡CCH₃) or ((CO)₂:(CH₃C≡CCH₃).

In an example embodiment, the metal organic precursor may include ethyl-cyclopentadienylcobalt-carbonyl (EtCpCo(CO)₂), ethylcyclopentadienyl-titanium-carbonyl (EtCpTi(CO)₂), or ethylcyclopentadienyl-nickel-carbonyl(EtCpNi(CO)₂).

In an example embodiment, the conductive pattern may be a polysilicon pattern or a single crystalline silicon pattern.

In an example embodiment, the substrate may have an insulation layer pattern thereon. The insulation layer pattern may have an opening exposing the conductive pattern.

In an example embodiment, when the preliminary metal silicide layer is formed, the metal organic precursor may be thermally decomposed at a temperature of about 300° C. to about 450° C. Metal separated from the metal organic precursor in the thermal decomposition may be deposited on the substrate. The metal deposited on the conductive pattern may be reacted with silicon included in the conductive pattern.

In an example embodiment, the metal deposited on the conductive pattern may be reacted with silicon simultaneously when metal is deposited on the substrate.

In an example embodiment, the preliminary metal silicide layer may be transformed into the metal silicide layer by a heat treatment at a temperature of about 500° C. to about 800° C.

In an example embodiment, a capping layer may be further formed on the preliminary metal silicide layer before the preliminary metal silicide layer is transformed into the metal silicide layer.

In an example embodiment, a portion of the metal layer on the substrate that is not formed on the conductive pattern may be removed, before the preliminary metal silicide layer is transformed into the metal silicide layer.

In an example embodiment, the conductive pattern may include an impurity region of a transistor on the substrate.

In an example embodiment, before performing the deposition process, an insulation layer pattern having an opening exposing an impurity region of the transistor may be formed.

In an example embodiment, the opening in the insulation layer pattern may be filled with a metal plug.

In an example embodiment, a capping layer may be formed on the preliminary metal silicide layer and the insulation layer pattern before transforming the preliminary metal silicide layer.

In an example embodiment, the metal layer may contain more carbon than metal by weight.

In an example embodiment, the metal layer may contain more than about 50% of carbon by weight.

According to example embodiments, a method of forming controlling a thickness of a silicide layer is provided. In the method, a silicon containing layer is formed. A metal-and-carbon containing compound is decomposed on the silicon-containing layer. The metal-and-carbon containing compound is caused to react with the silicon containing layer to from a silicided layer have a predetermined thickness. The thickness of the silicide layer is controlled by controlling a metal:carbon weight ratio of the metal-and-carbon containing compound

### BRIEF DESCRIPTION OF THE DRAWINGS

The above and other features and advantages will become more apparent to those of ordinary skill in the art by describing in detail exemplary embodiments with reference to the attached drawings, in which:

FIGS. 1 to 3 illustrate cross-sectional views of a method of forming an ohmic layer in accordance with example embodiments;

FIGS. 4 to 8 illustrate cross-sectional views of a method of forming a metal wiring of a semiconductor device in accordance with example embodiments;

FIG. 9 is a VSEM picture of step coverage characteristics of a cobalt layer formed in accordance with Example 1;

FIG. 10A is a SEM picture of a cobalt layer formed using CCTBA as a metal organic precursor;

FIG. 10B is a SEM picture of a cobalt layer formed using EtCpCo(CO)₂ as a metal organic precursor in accordance with Example 2;

FIG. 11A is a SEM picture of a cobalt silicide layer formed using CCTBA as a metal organic precursor;

FIG. 11B is a SEM picture of a cobalt silicide layer formed using EtCpCo(CO)₂ as a metal organic precursor in accordance with Example 3;

FIG. 12A illustrates a plot of sputtering time versus concentration of a metal layer formed using CCTBA as a metal organic precursor; and

FIG. 12B illustrates a plot of sputtering time versus concentration of a metal layer formed using EtCpCo(CO)2 as a metal organic precursor in accordance with Example 4.

### DETAILED DESCRIPTION

Korean Patent Application No. 2008-0020510, filed on Mar. 5, 2008, in the Korean Intellectual Property Office, and entitled: “Method of Forming an Ohmic Layer and Method of Forming a Metal Wiring of a Semiconductor Device Using the Same,” is incorporated by reference herein in its entirety.

Various example embodiments will be described more fully hereinafter with reference to the accompanying drawings, in which some example embodiments are shown. The present invention may, however, be embodied in many different forms and should not be construed as limited to the example embodiments set forth herein. Rather, these example embodiments are provided so that this disclosure will be thorough and complete, and will fully convey the scope of the present invention to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the present invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, example embodiments will be explained in detail with reference to the accompanying drawings.

In particular, according to example embodiments, an ohmic layer may be formed on a silicon substrate using a metal organic precursor including an alkyl-substituted cyclopentadienyl ligand and a carbonyl ligand bonded with an alkyl group by a deposition process, so that the ohmic layer may include a carbon content of above about 60%. As a result, the ohmic layer may not overly react with silicon in the substrate, allowing the ohmic layer to have a uniform thickness.

Additionally, while the deposition process is performed using the metal organic precursor, deposition of a metal layer and silicidation of the metal layer contacting the silicon substrate may be simultaneously performed, so that a preliminary metal silicide layer may be formed. Thus, a metal silicide layer having a desired crystalline property may be formed simply by performing a heat treatment on the preliminary metal silicide layer. As a result, productivity of manufacturing semiconductor devices may be improved.

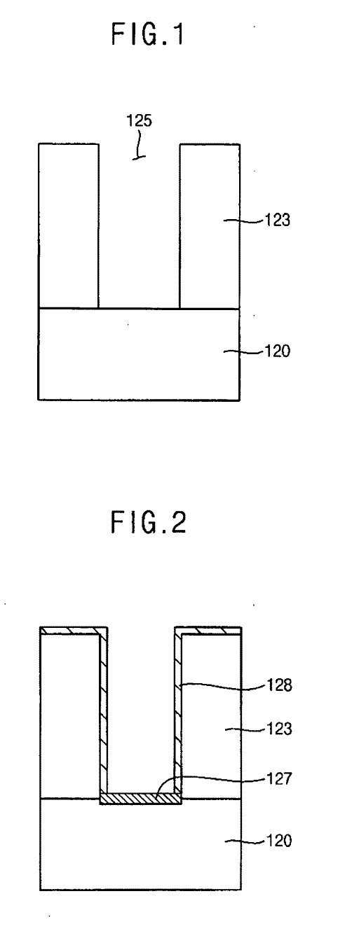

FIGS. 1 to 3 illustrate cross-sectional views of a method of forming an ohmic layer in accordance with example embodiments.

Referring to FIG. 1, a substrate 120 having a conductive pattern (not shown) therein is provided. The substrate 120 may include silicon. An insulation layer pattern 123 may be formed on the substrate 120. The insulation layer pattern 123 may have an opening 125 exposing the conductive pattern. The substrate 120 may further include conductive structures, e.g., a gate structure.

Particularly, an insulation layer may be formed on the substrate 120 including the conductive pattern. The insulation layer may include a boro-phosphosilicate glass (BPSG) layer, a phosphosilicate glass (PSG) layer, a spin-on glass (SOG) layer, a high density plasma (HDP) oxide layer, etc. The insulation layer may be formed using at lease one of the above layers. After forming an etching mask on the insulation layer, the insulation layer may be partially etched using the etching mask until the conductive pattern is exposed. Thus, the insulation layer pattern 123 having an opening 125 that exposes the conductive pattern may be formed. An upper portion of the insulation layer pattern 123 may be removed during the formation of the opening 125.

The conductive pattern may include a doped single crystalline silicon pattern, a doped polysilicon pattern a doped silicon-germanium pattern, etc. The conductive pattern may be a source/drain region in the substrate 120, a portion of a doped polysilicon layer, or a portion of a single crystalline silicon layer formed by an epitaxial growth process.

Referring to FIG. 2, a metal layer 128 and a preliminary metal silicide layer 127 may be simultaneously formed by a deposition process using a metal organic precursor.

The metal layer 128 and the preliminary metal silicide layer 127 may be formed by a chemical vapor deposition (CVD) process, a cyclic-CVD process, an atomic layer deposition (ALD) process, etc. In the CVD process, after a metal organic precursor is provided into a chamber where the substrate 120 is loaded, the metal organic precursor is thermally decomposed. Thus, metal atoms separated from ligands of the metal organic precursor, as well as carbon from the metal organic precursor, are deposited on a top surface of the substrate 120.

The metal organic precursor may be represented by a formula of R₁-CpML. In the formula, R₁ is an alkyl group substituent of Cp, R₁ including methyl; ethyl, propyl, pentamethyl, pentaethyl, diethyl, dimethyl, dipropyl, etc. Cp is cyclopentadienyl. M may include nickel (Ni), cobalt (Co), titanium (Ti), platinum (Pt), zirconium (Zr), or ruthenium (Ru). L is at least one ligand, the at least one ligand including a carbonyl. For example, L may be represented by formulas such as (CO)₂, (CO)₃(NO), (CO)₆:(HC≡CtBu), (CO)₆:(HC≡CPh), (CO)₆:(HC≡CH), (CO)₆:(HC≡CCH3), (CO)₆:(CH₃C≡CCH₃), (CO)(NO), (CO)₂:(HC≡CtBu), (CO)₂:(HC≡CPh) (CO)₂:(HC≡CH), (CO)₂:(HC≡CCH₃), (CO)₂:(CH₃C≡CCH₃), etc.

The metal organic precursor may include an alkyl-group-substituted cyclopentadienyl ligand and carbonyl ligand bonded. In contrast, the use of a metal organic precursor including cyclopentadienyl ligand alone may prevent the metal organic precursor from being efficiently deposited.

In particular, the metal organic precursor may include one or more of ethylcyclopentadienyl-cobalt-carbonyl (EtCpCo(CO)₂), ethylcyclopentadienyl-titanium-carbonyl (EtCpTi(CO)₂), ethylcyclopentadienyl-nickel-carbonyl (EtCpNi(CO)₂), etc., each of which has a large amount of carbon.

The metal organic precursor may be stored in a canister at a temperature of about 20° C. to about 40° C., and may be thermally decomposed at a high temperature, e.g., about 300° C. to about 450° C.

The metal organic precursor according to embodiments by the formula may be easily deposited at a high temperature and thermally decomposed at a high temperature. Thus, the amount of carbon in a metal layer or a metal silicide layer successively formed may be readily controlled.

The metal layer 128 and the preliminary metal silicide layer 127 may be simultaneously formed by the following processes. After the substrate 120 is loaded in a CVD chamber maintained at a temperature of about 300° C. to about 450° C., the metal organic precursor represented by the formula may be provided onto the substrate 120. The metal organic precursor may be thermally decomposed, so that ligands of the metal organic precursor may be separated from metal atoms thereof. Accordingly, the metal organic precursor including the metal atoms may be deposited on the substrate 120. The deposition of the metal atoms may occur on the insulation layer pattern 123 and the conductive pattern of the substrate 120.

The metal atoms deposited on the conductive pattern of the substrate may be reacted with silicon to form the preliminary metal silicide layer 127 by a first silicidation process. The first silicidation process may be performed simultaneously when the metal atoms are deposited on the conductive pattern. The preliminary metal silicide layer 127 may include impurities, e.g., carbon generated from the ligand, so that the preliminary metal silicide layer 127 may not overly react with the silicon of the substrate 120.

Meanwhile, the metal atoms deposited on the insulation layer pattern 123 may not be silicided, so that the metal layer 128 may be formed. Formation of the metal layer 128 may occur simultaneously with the formation of the preliminary metal silicide layer 127.

Referring to FIG. 3, the preliminary metal silicide layer 127 may be transformed into a metal silicide layer 130. The metal silicide layer 130 may include a cobalt silicide layer, a nickel silicide layer, a titanium silicide layer, etc. In the present embodiment, the metal silicide layer 130 is the cobalt silicide layer.

Particularly, the metal silicide layer 130, e.g., the cobalt silicide (CoSi₂) layer, may be formed by a second silicidation process in which a heat treatment process is performed on the preliminary cobalt silicide (CoSi) layer. The heat treatment process may be performed at a temperature of about 500° C. to about 900° C., preferably, at a temperature of about 500° C. to about 800° C. As a result, the preliminary cobalt silicide layer may be transformed into the cobalt silicide layer. The preliminary cobalt silicide layer includes impurities such as carbon, so that the preliminary cobalt silicide layer may not be overly reacted with the silicon of the substrate 120.

Before forming the metal silicide layer 130 by the heat treatment process, an etching process may be further performed so as to remove residues on the metal layer 128 and the preliminary metal silicide layer 127. That is, the etching process may be performed to remove residues of the preliminary metal silicide layer 127 and the metal layer 128 remaining on the insulation layer pattern 123.

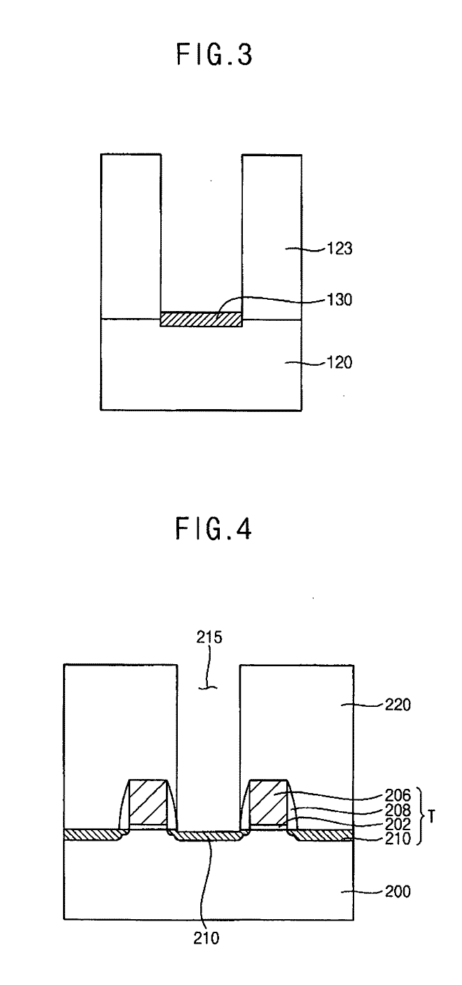

FIGS. 4 to 8 illustrate cross-sectional views of a method of forming a metal wiring of a semiconductor device in accordance with example embodiments. In this method, an ohmic layer may be formed by the above-described method with reference to FIGS. 1 to 3.

Referring to FIG. 4, an insulation layer may be formed on a substrate 200 to cover a transistor T on the substrate 200.

The substrate 200 may include silicon. The transistor T may include a gate insulation layer 202, a gate electrode 206, a gate spacer 208, and an impurity region 210. The gate electrode 206 may include polysilicon doped with impurities and the impurity region 210 may serve as a source/drain region, which may be formed by doping impurities at an upper portion of the substrate 200. The gate spacer 208 may be on a sidewall of the gate electrode 206. The insulation layer may be formed using silicon oxide by a spin coating process or a chemical vapor deposition (CVD) process. The insulation layer may have a planarized top formed by a chemical mechanical polishing (CMP) process and/or an etch back process.

The insulation layer may be patterned to form an insulation layer pattern 220 having an opening 215 exposing the impurity region 210. The insulation layer pattern 220 may be formed by an etching process using an etching mask. Alternatively, the insulation layer pattern 220 may be directly provided, without using an insulation layer to be patterned. Hereinafter, the impurity region 210 is called as a source/drain 210.

Referring to FIG. 5, a deposition process may be performed using a metal organic precursor to form a preliminary metal silicide layer 228 on a top surface of the source/drain 210 exposed by the opening 215 and to form a metal layer 227 on the insulation layer pattern 220. The metal organic precursor may be represented by the formula of R₁-CpML described above.

The method of forming the preliminary metal silicide layer 228 and the metal layer 227 are illustrated with reference to FIG. 3. Thus, details thereof will not be repeated.

Referring to FIG. 6, after the metal layer 227 remaining on the insulation layer pattern 220 is removed, the preliminary metal silicide layer 228 is reacted with silicon included in the source/drain 210 to form a metal silicide layer 230. Particularly, the metal silicide layer 230 having a formula of M—Si₂, e.g., CoSi₂, may be formed by performing a heat treatment process on the preliminary metal silicide layer 228 having a formula of M—Si, e.g., CoSi.

The method of forming the metal silicide layer 230 may be substantially the same as that illustrated with reference to FIG. 3. Thus, details thereof will not be repeated.

Referring to FIG. 7, a capping layer 240 may be uniformly formed on the metal silicide layer 230 and the insulation layer pattern 220. The capping layer 240 may be formed using a metal and/or a metal nitride. In the present embodiment, the capping layer 240 may include a titanium layer and a titanium nitride layer. Alternatively, the capping layer 240 may be formed on the preliminary metal silicide layer 228 and the insulation layer pattern 220. That is, the capping layer may be formed before performing the heat treatment process on the preliminary metal silicide layer 228 to form the metal silicide layer 230.

Referring to FIG. 8, a conductive plug 250 filling the opening 215 may be formed. Particularly, a conductive layer may be formed to fill the opening 215. The conductive layer may include tantalum (Ta), copper (Cu), tungsten (W), titanium (Ti), aluminum (Al), etc. In the present embodiment, the conductive layer is tungsten. The conductive layer may be formed by a CVD process or a physical vapor deposition (PVD) process, e.g., a sputtering method. The conductive layer may be removed until the insulation layer pattern 220 is exposed, e.g., by a CMP process and/or an etch back process. Accordingly, the conductive plug 250 may be electrically connected to the source/drain region 210.

The following description demonstrates advantages of using a metal organic precursor including an alkyl-group-substituted cyclopentadienyl ligand and a carbonyl ligand.

### EXAMPLE 1

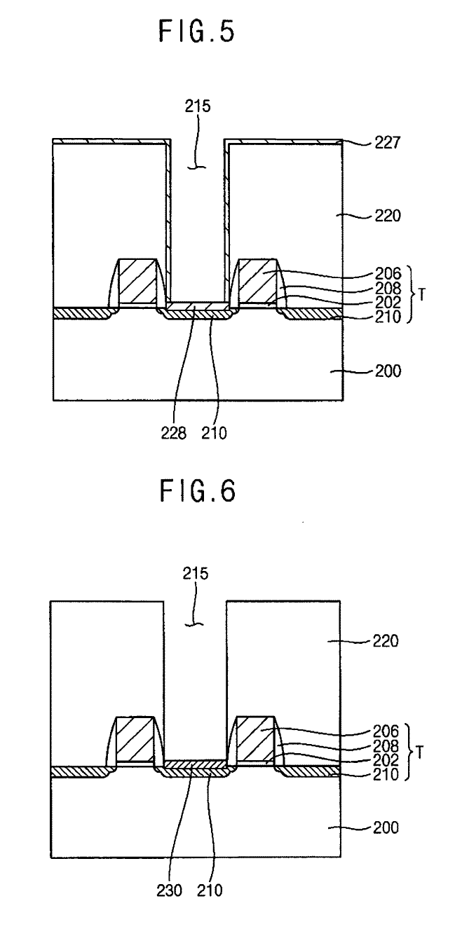

EtCpCo(CO)₂ serving as a metal organic precursor in a MOCVD process was provided into a chamber maintained at a temperature of about 400° C. to form a cobalt layer on a substrate having steps therein. The cobalt layer is shown in FIG. 9, which is a virtual scanning electron microscope (VSEM) picture.

Referring to FIG. 9, the cobalt layer formed using EtCpCo(CO)₂ has a high step coverage, e.g., a step coverage of about 90%. When compared to a conventional cobalt layer formed using dicobalt hexacarbonyl t-butylacetylene (CCTBA), the cobalt layer formed using EtCpCo(CO)₂ has better step coverage because the cobalt layer formed using EtCpCo(CO)₂ is thermally decomposed at a higher temperature.

### COMPARATIVE EXAMPLE 2

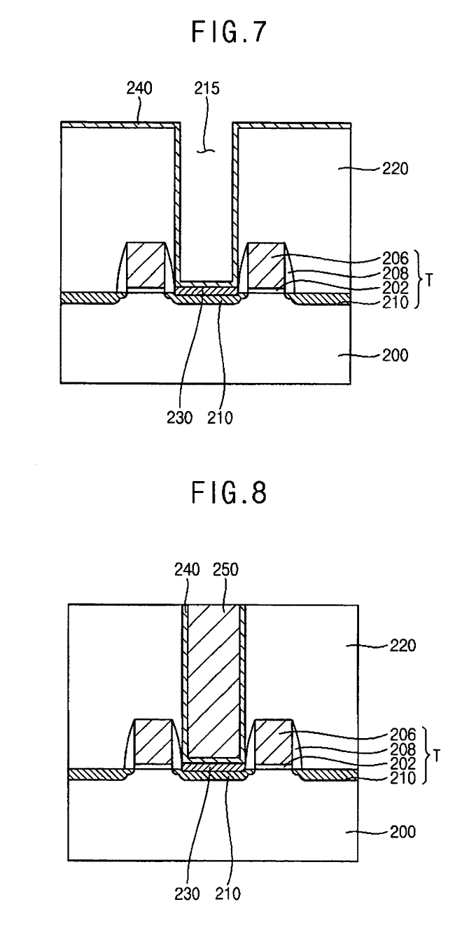

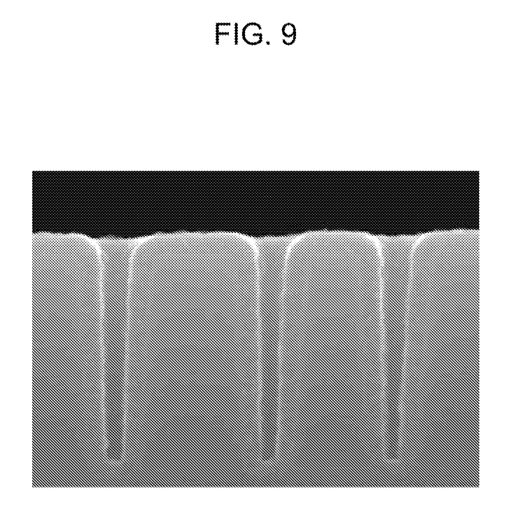

A cobalt layer was deposited on a substrate having a silicon oxide layer thereon to a thickness of about 100 Å using CCTBA as a metal organic precursor, and then was thermally treated at a temperature of about 600° C. A top surface of the resultant cobalt layer observed by an electron microscope is shown in FIG. 10A.

### EXAMPLE 2

A cobalt layer was formed on a substrate having a silicon oxide layer thereon to a thickness of about 100 Å using EtCpCo(CO)₂ as a metal organic precursor, and then was thermally treated at a temperature of about 600° C. A top surface of the resultant cobalt layer observed by an electron microscope is shown in FIG. I OB.

As can be seen in FIG. 10A, strong agglomeration occurred in the cobalt layer formed using CCTBA on the underlying silicon oxide layer. In contrast, as can be seen in FIG. 10B, agglomeration in the cobalt layer formed using EtCpCo(CO)₂ on the underlying silicon oxide layer is much less pronounced.

### COMPARATIVE EXAMPLE 3

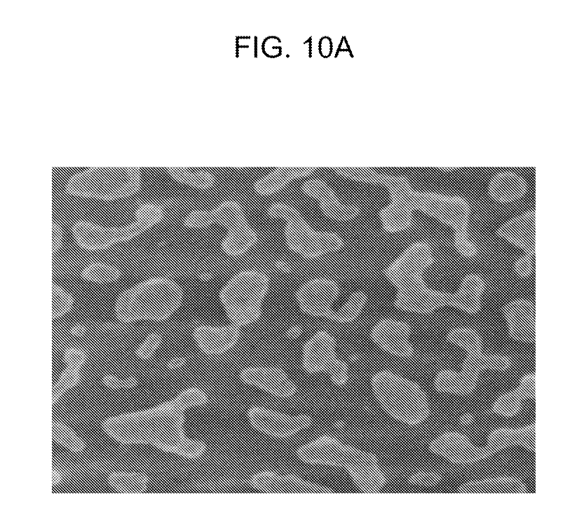

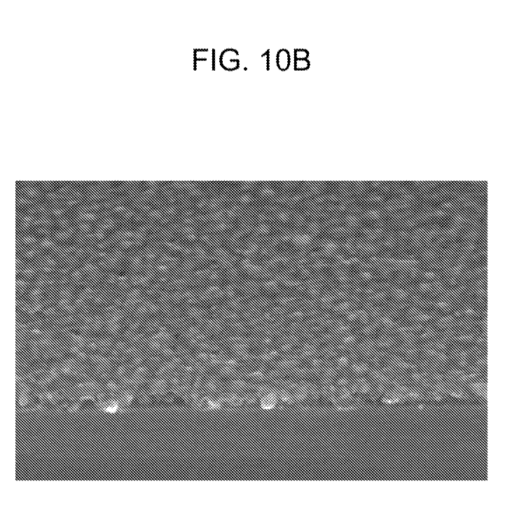

A metal wiring including a cobalt silicide layer at a bottom portion thereof was formed using CCTBA as a metal organic precursor to contact a source/drain region of a substrate. The resultant structure observed by an electron microscope is shown in FIG. 11A.

### EXAMPLE 3

A metal wiring including a cobalt silicide layer at a bottom portion thereof was formed using EtCpCo(CO)₂ as a metal organic precursor to contact a source/drain region of a substrate. The resultant structure observed by an electron microscope is shown in FIG. 11B.

Referring to FIG. 11A, the cobalt silicide layer formed using CCTBA was grown to a large thickness on a portion of the substrate. Referring to FIG. 11B, the cobalt silicide layer formed using EtCpCo(CO)₂ was not grown to a large thickness on a portion of the substrate. In particular, the cobalt silicide layer formed using EtCpCo(CO)₂ was grown to a thickness of about one-third of that of the cobalt silicide layer formed using CCTBA.

### COMPARATIVE EXAMPLE 4

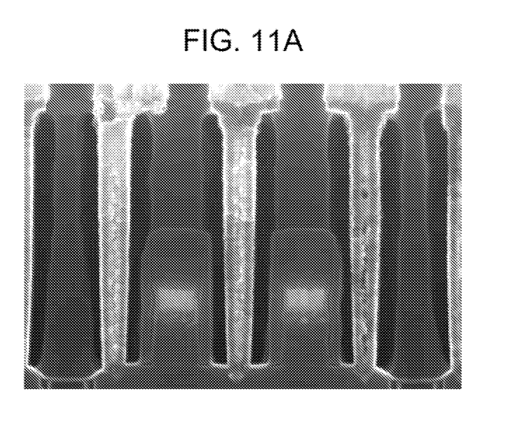

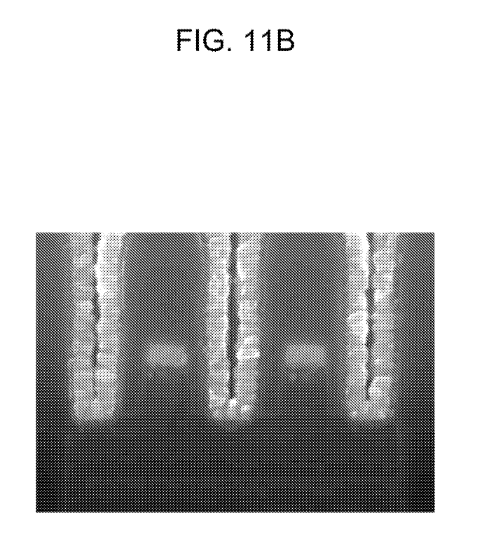

A metal layer was formed on a silicon substrate using CCTBA as a metal organic precursor, and a sputtering analysis was performed on the metal layer to measure components of the metal layer. The result is shown in FIG. 12A.

### EXAMPLE 4

A metal layer was formed on a silicon substrate using EtCpCo(CO)₂ as a metal organic precursor, and a sputtering analysis was performed on the metal layer to measure components of the metal layer. The result is shown in FIG. 12B.

Referring to FIG. 12A, the metal layer formed using CCTBA includes about 60% by weight of cobalt, about 35% by weight of carbon and about 5% by weight of oxygen. Referring to FIG. 12B, the metal layer formed using EtCpCo(CO)₂ includes about 30% by weight of cobalt, about 65% by weight of carbon and about 5% by weight of oxygen. EtCpCo(CO)₂ is not easily thermally decomposed even at a high temperature. Thus, the metal layer formed using EtCpCo(CO)₂ as a metal organic precursor may include a high concentration, e.g., about 60% by weight, of carbon. As a result, the metal layer may be prevented from overly reacting with silicon, so that the resultant metal silicide layer may not have a large thickness.

According to example embodiments, an ohmic layer may be formed on a silicon substrate using a metal organic precursor including an alkyl-group-substituted cyclopentadienyl ligand and a carbonyl ligand by a deposition process, so that the ohmic layer may include a carbon content of above about 60%. As a result, the ohmic layer may not overly react with silicon in the substrate, allowing the ohmic layer to have a uniform thickness. Additionally, while the deposition process is performed using the metal organic precursor, deposition of a metal layer and silicidation of the metal layer contacting the silicon substrate may be simultaneously performed, so that a preliminary metal silicide layer may be formed. Thus, a metal silicide layer having a desired crystalline property may be formed simply by performing a heat treatment on the preliminary metal silicide layer. As a result, productivity of manufacturing semiconductor devices may be improved.

Exemplary embodiments of the present invention have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. A method of forming an ohmic layer, the method comprising:
performing a deposition process of a metal organic precursor represented by a following formula (1) to form a preliminary metal silicide layer and a metal layer on a substrate having a conductive pattern including silicon, the preliminary metal silicide layer being formed on the conductive pattern; and
transforming the preliminary metal silicide layer into a metal silicide layer,
R₁-CpML (1)
wherein, R₁ is an alkyl group substituent of Cp, R₁ including one of methyl, ethyl, propyl, pentamethyl, pentaethyl, diethyl, dimethyl and dipropyl, Cp is cyclopentadienyl, M includes at least one of nickel (Ni), cobalt (Co), titanium (Ti), platinum (Pt) zirconium (Zr) and ruthenium (Ru), and L is at least one ligand, the at least one ligand including a carbonyl.

2. The method as claimed in claim 1, wherein L includes one of (CO)₂, (CO)₃(NO), (CO)₆:(HC≡CtBu), (CO)6:(HC≡CPh), (CO)₆:(HC≡CH), (CO)₆:(HC≡CCH₃), (CO)₆:(CH₃C≡CCH₃), (CO)(NO), (CO)₂:(HC≡CtBu), (CO)₂:(HC≡CPh) (CO)₂:(HC≡CH), (CO)₂:(HC≡CCH₃) and ((CO)₂:(CH₃C≡CCH₃).

3. The method as claimed in claim 1, wherein the metal organic precursor includes one of ethylcyclopentadienyl-cobalt-carbonyl(EtCpCo(CO)₂), ethylcyclopentadienyl-titanium-carbonyl(EtCpTi(CO)₂), and ethylcyclopentadienyl-nickel-carbonyl (EtCpNi(CO)₂).

4. The method as claimed in claim 1, wherein the conductive pattern is a polysilicon pattern or a single crystalline silicon pattern.

5. The method as claimed in claim 1, wherein the substrate has an insulation layer pattern thereon, the insulation layer pattern including an opening exposing the conductive pattern.

6. The method as claimed in claim 1, wherein forming the preliminary metal silicide layer comprises:
thermally decomposing the metal organic precursor at a temperature of about 300° C. to about 450° C.;
depositing metal on the substrate, the metal being separated from the metal organic precursor in the thermal decomposition; and
reacting the metal deposited on the conductive pattern.

7. The method as claimed in claim 6, wherein reacting the metal deposited on the conductive pattern is simultaneously performed with depositing metal on a non-silicon containing portion of the substrate.

8. The method as claimed in claim 1, wherein transforming the preliminary metal silicide layer into the metal silicide layer is performed by a heat treatment at a temperature of about 500° C. to about 800° C.

9. The method as claimed in claim 1, further comprising forming a capping layer on the preliminary metal silicide layer before transforming the preliminary metal silicide layer into the metal silicide layer.

10. The method as claimed in claim 1, further comprising removing a portion of the metal layer on the substrate that is not formed on the conductive pattern before transforming the preliminary metal silicide layer into the metal silicide layer.

11. The method as claimed in claim 1, wherein the conductive pattern includes an impurity region of a transistor on the substrate.

12. The method as claimed in claim 11, wherein the metal organic precursor includes one of ethylcyclopentadienyl-cobalt-carbonyl(EtCpCo(CO)₂), ethylcyclopentadienyl-titanium-carbonyl(EtCpTi(CO)₂), and ethylcyclopentadienyl-nickel-carbonyl (EtCpNi(CO)₂).

13. The method as claimed in claim 11, further comprising, before performing the deposition process, forming an insulation layer pattern on the substrate, the insulation layer pattern including an opening exposing the impurity region of the transistor.

14. The method as claimed in claim 13, further comprising filling the opening with a metal plug.

15. The method as claimed in claim 14, further comprising, before transforming the preliminary metal silicide layer, forming a capping layer on the preliminary metal silicide layer and the insulation layer pattern.

16. The method as claimed in claim 15, wherein transforming the preliminary metal silicide layer includes performing a heat treatment.

17. The method as claimed in claim 1, wherein transforming the preliminary metal silicide layer includes performing a heat treatment.

18. The method as claimed in claim 1, wherein the metal layer contains more carbon than metal by weight.

19. The method as claimed in claim 18, wherein the metal layer contains more than about 50% of carbon by weight.

20. A method of controlling a thickness of a silicide layer, the method comprising:
forming a silicon containing layer;
decomposing a metal-and-carbon containing compound on the silicon-containing layer; and
causing the metal-and-carbon containing compound to react with the silicon containing layer to form the silicide layer having a predetermined thickness, wherein controlling the thickness of the silicide layer including controlling a metal:carbon weight ratio of the metal-and-carbon containing compound.
